(19) United States
(12) Patent Application Publication
(10) Pub. No.: US 2011/0019345 A1
(43) Pub. Date: Jan. 27, 2011

(54) IMAGE DISPLAY APPARATUS

(75) Inventors: Akira Hayama, Sagamihara-shi (JP); Kinya Kamiguchi, Kamakura-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/835,845

(22) Filed: Jul. 14, 2010

(30) Foreign Application Priority Data
Jul. 24, 2009 (JP) 2009-172974

(51) Int. Cl. H05K 7/00

(52) U.S. Cl. 361/679.01

(57) ABSTRACT

A spacer 4 has a protrusion 21 on the side where the spacer 4 contacts a rear plate 2 or face plate 1, and a buffer 20 is disposed between the spacer 4 and the plate on the side where the protrusion 21 is provided. The buffer 20 to be used has an appropriate elastic modulus.

### BACKGROUND OF THE INVENTION

1. Field of the Invention

The present invention relates to an image display apparatus which has electron-emitting devices, and more particularly to an image display apparatus which has spacers between a rear plate having electron-emitting devices and a face plate having a light emitting member.

2. Description of the Related Art

A flat image display apparatus using electron-emitting devices, such as a surface-conduction electron-emitting devices, are proposed as an image display apparatus that can be slimmer and lighter. This display apparatus has a rear plate having electron-emitting devices, and a face plate having a light emitting member that emits light when electrons are irradiated. The rear plate and the face plate are disposed so as to face each other, and the edges of these plates are sealed by a frame to be a vacuum housing. In order to prevent deformation and damage of the substrates caused by a difference in atmospheric pressure between the inside and outside of the vacuum housing, supporting members called “spacers” are disposed between the substrates. A plurality of spacers are normally disposed in the vacuum housing, and the heights of the plurality of spacers are demanded to be uniform in order to prevent damage of the housing and to display good quality images. U.S. Pat. No. 3,699,565 discloses a configuration of disposing flexible metal members between the rear plate or face plate and the spacers, so that the tolerance of the heights of the spacers is relaxed.

### SUMMARY OF THE INVENTION

In order to prevent damage of the vacuum housing and maintain excellent image quality, it is necessary to dispose the spacers perpendicular to the rear plate and face plate without inclining.

The present invention provides an image display apparatus of which deformation and damage are prevented by disposing the spacers perpendicular to the rear plate and the face plate, without inclining with respect to the plates.

An image display apparatus according to the present invention, comprising:

a rear plate having electron-emitting devices;

a face plate having a light emitting member which emits light by irradiation of electrons emitted from the electron-emitting devices;

a spacer disposed between the rear plate and face plate, and having a protrusion on the side facing the rear plate or face plate; and

a buffer disposed between the rear plate or face plate and the protrusion, wherein

the following Expression (1) is satisfied.

F/S<a<(t/(0.6×L))×(F/S) (1)

where L [m] denotes a height of the protrusion, t [m] denotes a thickness of the buffer in a position in contact with the outer periphery of the spacer, a [MPa] denotes an elastic modulus of the buffer, F [MPa·m²] denotes the total amount of force applied to a contact portion between the buffer and the spacer, and S [m²] denotes the total area of the contact portion.

According to the present invention, an image display apparatus which displays with high image quality and has high reliability with preventing deformation and damage, by the protrusions of the spacers for suppressing inclination of the spacers with respect to the plates, is provided.

Further features of the present invention will become apparent from the following description of exemplary embodiments with reference to the attached drawings.

### BRIEF DESCRIPTION OF THE DRAWINGS

FIG. 1 is a schematic depicting the configuration example of an image display apparatus of the present invention;

FIG. 2A to FIG. 2C are schematics depicting a general configuration of the image display apparatus of the present invention;

FIG. 3A to FIG. 3C are schematics depicting a spacer and a buffer according to the present invention;

FIG. 4A to FIG. 4D are schematics depicting the function of the buffer according to the present invention;

FIG. 5 is a plan view of the rear plate according to an example of the present invention; and

FIG. 6A and FIG. 6B are graphs showing the result of the example of the present invention.

### DESCRIPTION OF THE EMBODIMENTS

The relationship between the elastic modulus of the buffer and the protruding shape of the contact surface of the spacer, which is characteristic of the present invention, will now be described.

The image display apparatus of the present invention has a rear plate having electron-emitting devices and a face plate having a light emitting member, which emits light by the irradiation of electrons emitted from the electron-emitting devices. Examples of an electron-emitting device are an FED and a surface-conduction electron-emitting device. Spacers are disposed between the rear plate and the face plate. In the present invention, this spacer has a protrusion to a side facing the rear plate or face plate, and a buffer is disposed between this protrusion and plate.

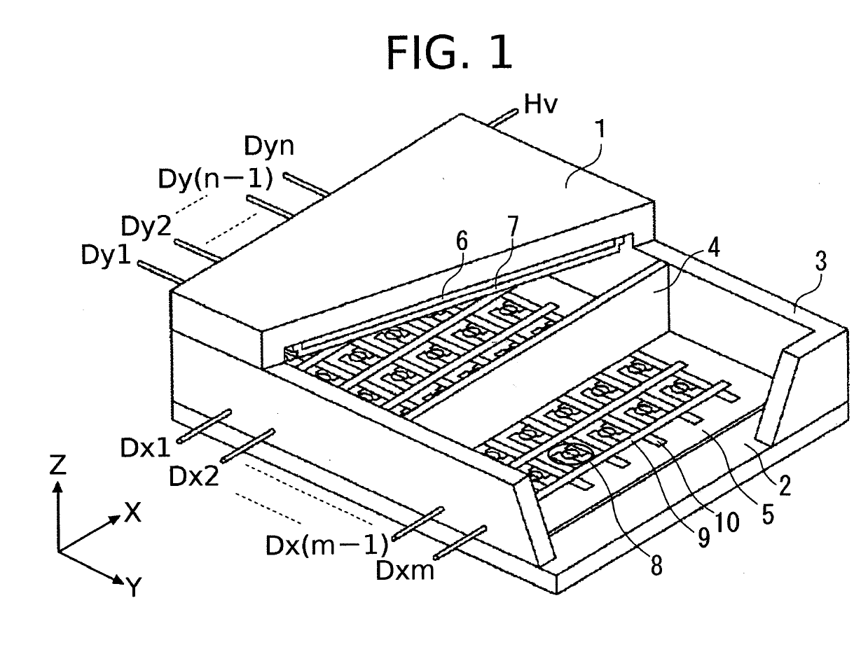

FIG. 1 is a schematic depicting the configuration of a display panel (air-tight housing) of an example of the image display apparatus of the present invention. FIG. 1 shows an example of a display panel of an image display apparatus constituted by electron sources arranged in a simple matrix. In FIG. 1, a partially cut-away view of the display panel is shown. In FIG. 1, a reference numeral 1 denotes a face plate which is a glass substrate. The face plate 1 has a fluorescent film 6 which is a phosphor as a light emitting member, and a metal back 7 which is an anode, on the inner surface thereof. A reference numeral 2 denotes a rear plate. The rear plate 2 has an electron source substrate 5 having electron emitting devices 8, X direction wirings 9 and Y direction wirings 10. A reference numeral 3 is a supporting frame. The rear plate 2 and the face plate 1 are installed on the supporting frame 3 via frit glass, for example, and constitutes the air-tight housing (enclosure). In this example, the electron source substrate 5 is placed on the rear plate 2, but this configuration is only for reinforcing the strength of the electron source substrate 5. Hence the electron-emitting devices 8 and wirings may be directly formed on the rear plate 2 only if sufficient strength can be obtained.

As the electron-emitting device 8, such a cold-cathode device as a surface-conduction type, FE type or MIM type, is used. The electron beam from the electron-emitting devices 8, formed on the rear plate 2, is accelerated by a desired acceleration voltage supplied to the face plate 1, and is irradiated onto the face plate 1. At this time, the phosphor emits light by the collision of electrons onto the fluorescent film 6 formed on the face plate 1, and an image is displayed on the face plate 1.

The spacers 4, as supporting members, are disposed between the face plate 1 and the rear plate 2, so as to provide sufficient strength against atmospheric pressure. In the present invention, a configuration other than disposing a buffer between the spacer 4 and the face plate 1 or rear plate 2 is the same as prior art.

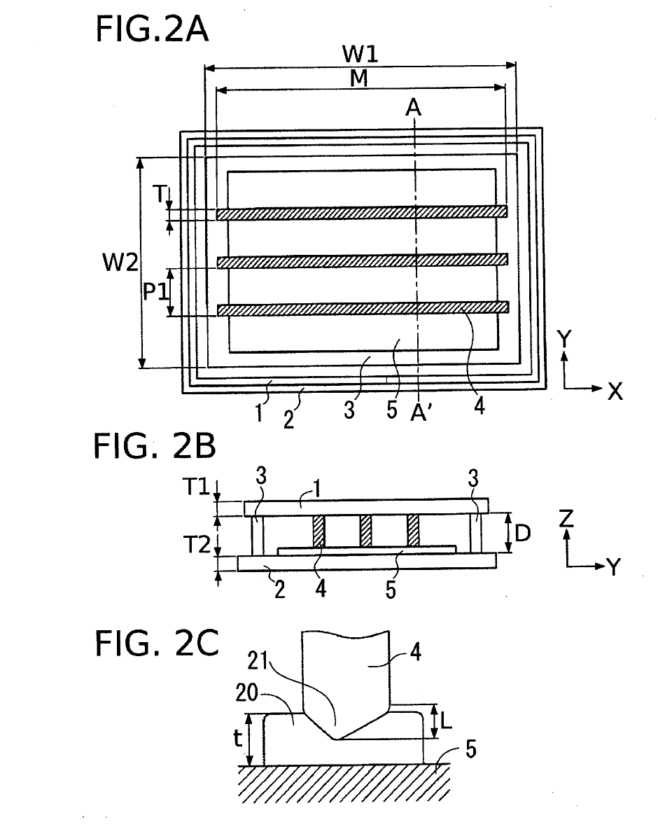

FIG. 2A to FIG. 2C are diagrams further depicting the device in FIG. 1. FIG. 2A is a plan view, FIG. 2B is a cross-sectional view sectioned by A-A′ in FIG. 2A, and FIG. 2C is an enlarged view of an area around the contact portion between the spacer 4 and the electron source substrate 5. A reference numeral 20 in FIG. 2C denotes the buffer, and a reference numeral 21 denotes a protrusion of the spacer 4.

As FIG. 2A and FIG. 2B show, according to the image display apparatus of the present invention, the rear plate 2, face plate 1 and supporting frame 3 are hermetically bonded by frit glass, and the inner dimension of the supporting frame 3 in the X direction is W1, and the dimension in the Y direction is W2. The spacer 4 is a plate type (length in the X direction is M, and length in the Y direction is T), which is disposed in the Y direction with the spacing P1, so as to maintain the distance between the face plate 1 and the rear plate 2 at a predetermined distance D. As mentioned above, the spacer 4 supports the external force corresponding to the atmospheric pressure P (0.1 MPa), which is applied to the face plate 1 and the rear plate 2. The total load thereof corresponds to the load (P×A), that is the atmospheric pressure multiplied by the internal cross-sectional area A (=W1×W2) of the image display apparatus. This load is dispersed and supported by a plurality of spacers 4.

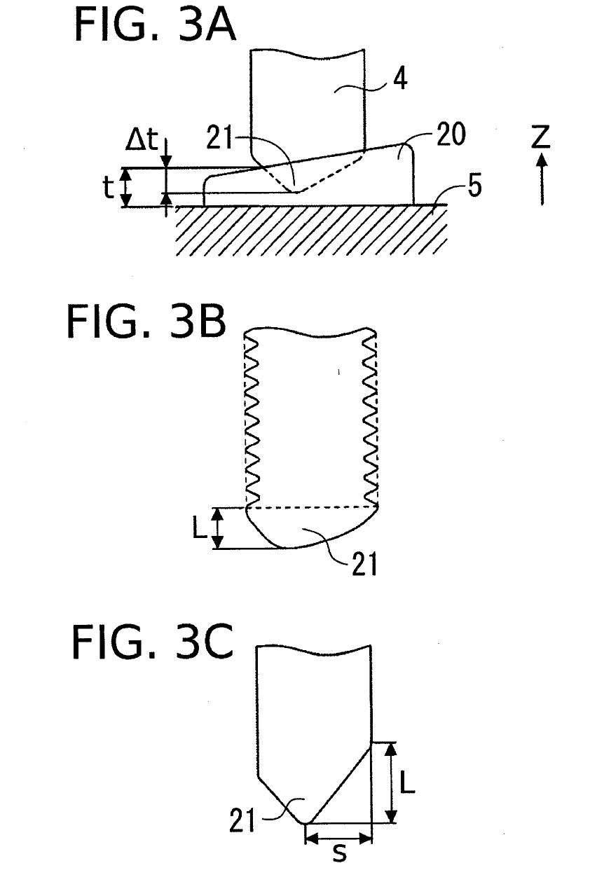

The contact state of the spacer 4 and the rear plate 2 is described with reference to FIG. 2C. A buffer 20, of which elastic modulus is a and thickness is t, is disposed between the spacer 4 and the rear plate 2. Further, a protrusion 21 having a height L exists on the surface of the spacer 4 where the spacer 4 contacts the buffer 20. The thickness t and the height L of the protrusion are described in detail with reference to FIG. 3A to FIG. 3C.

The thickness t of the buffer 20 is a thickness of the buffer 20 from the surface on which the buffer 20 is disposed (surface of the electron source substrate 5 in FIG. 2A to FIG. 2C), to the position in contact with the outer periphery of the spacer 4. If this thickness is not even, the smallest thickness, among the thicknesses of the buffer 20 up to the position in contact with the outer periphery of the spacers 4, is regarded as the thickness t as shown in FIG. 3A.

The height L of the protrusion 21 of the spacer 4 is a height of the protrusion 21 existing in the contact surface of the spacer 4 and the buffer 20. More specifically, the protruded portion, surrounded by the outermost periphery of the spacer 4 inside the surface in parallel with the Z direction, is called the protrusion 21, and if the spacer 4 has an unevenness on the surface in parallel with the Z direction, the height of the protrusion 21 is regarded as the height L, as shown in FIG. 3B. If the shape of the protrusion 21 is asymmetric, the height in the location of which distance from the vertex of the protrusion 21 to the outermost periphery surface of the spacer 4 is longest, is regarded as the height L [m], as shown in FIG. 3C. In the case of a spacer 4 which satisfies L/s<1.75×10⁻³ where s [m] denotes the distance from the vertex of the protrusion 21 to the outermost periphery surface of the spacer 4, even if the spacer 4 is inclined, the inclination is ±0.1° at the maximum, which hardly influences the display panel, as mentioned later. If L/s has a plurality of values, depending on the shape of the protrusion 21, it is sufficient if the maximum value thereof satisfies the above relational expression.

Here if the total force applied to all of the contact portion of the spacer 4 is F [MPa·m²] and the area of all of the contact portion of the spacer 4 (area of cross-section in parallel with the XY directions) is S [m²], then F=P×A, and the depressed amount Δt [m] of the buffer 20 is determined as follows.

Δt=(t/a)×(F/S)

The depressed amount Δt is a depth in the Z direction of the depressed portion formed in the buffer 20 by the protrusion 21 of the spacer 4, and is a length in the Z direction from a thinnest position of the buffer 20 among positions in contact with the outer periphery of the spacer 4 to the deepest position of the protrusion 21 embedded in the buffer 20. If the shape of the buffer 20 is uneven, the depressed amount Δt, shown in FIG. 3A, is regarded as the depressed amount Δt.

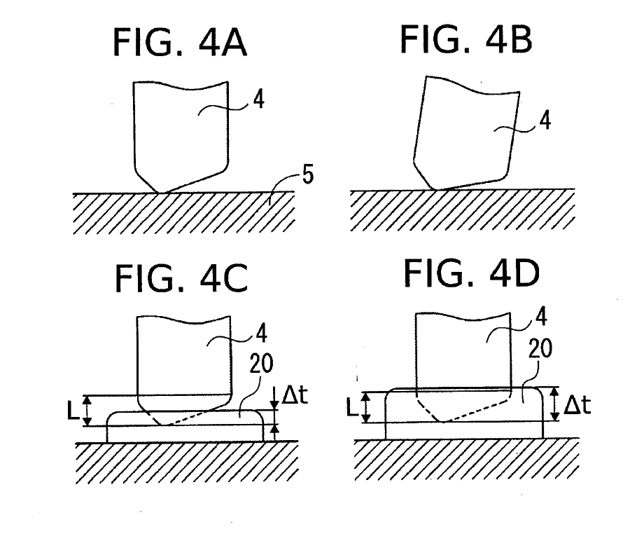

Now the role of the buffer 20 will be described. FIG. 4A shows a contact state of the spacer 4 and the substrate 5 when the buffer 20 does not exist. Since the protrusion 21 and an inclination exist in the contact face of the spacer 4, it is possible that the spacer 4 does not contact perpendicularly to the substrate 5 (specifically, the wirings). In this case, a rotational moment is applied to the spacer 4, and the spacer 4 is inclined as shown in FIG. 4B. This inclination of the spacer 4 distorts the electric field near the spacer 4, affects the electron orbit, and causes deterioration of the image quality. If the inclination is major, the spacer 4 itself may fall down during or after fabrication of the display panel, which may destroy a panel. The present inventors investigated the influence of this inclination, and confirmed that image quality begins to be affected if the inclination of the spacer 4 exceeds ±0.1°, and the possibility of a spacer 4 falling down increases if ±0.3° is exceeded. FIG. 4C and FIG. 4D show cases when the buffer 20 exists. If the buffer 20 has an appropriate elastic modulus, the rotational moment generated by the protrusion 21 at the edge of the spacer 4 can be decreased by the buffer 20 that is depressed. The condition for this is that the depressed amount Δt of the buffer 20 must be smaller than the thickness t of the buffer 20. This is the because if the elastic modulus a [MPa] is too small, the buffer 20 becomes too soft to support a spacer. Therefore t>Δt=(t/a)×(F/S), which means that F/S<a.

If the buffer 20 is too hard, on the other hand, the protrusion 21 cannot be absorbed, so the buffer 20 must be appropriately soft according to the shape of the protrusion 21. The present inventors determined, by experiments, that α=0.6 is required to decrease the inclination of the spacer 4 when Δt>α×L. In qualitative terms, this means that the contacts of the spacer 4 and the buffer 20 increase by the depression of the buffer 20, the point load becomes a distributed load, and the moment applied to the spacer 4 is also distributed by the protrusion 21, and as a result, the spacer 4 does not easily fall down. The inclination of the spacer 4 at this time can be maintained to within ±0.3°.

Therefore Δt=(t/a)×(F/S)>0.6×L, which means that a<t/(0.6×L)×(F/S), and these expressions together establish F/S<a<t/(0.6×L)×(F/S).

As described above, the image display apparatus of the present invention satisfies

F/S<a<t/(0.6×L)×(F/S) (1)

In the present invention, it was determined, by experiments, that α=1 is preferable when Δt>α×L in order to further decrease the inclination of the spacer 4 within a range of satisfying Expression (1). This means, in qualitative terms, that the protrusion 21 is completely embedded in the buffer 20, by a depression of the buffer 20, as shown in FIG. 4D. In this case, the moment that is applied to the spacer by the protrusion 21 becomes virtually nonexistent, and the spacer 4 is less likely to fall down. The inclination of the spacer at this time can be controlled to be within ±0.1°, and an even higher image quality can be implemented.

Therefore Δt=(t/a)×(F/S)>1.0×L, which means a<t/L×(F/S), and these expressions together establish F/S<a<(t/L)×(F/S).

As described above, it is preferable to satisfy

F/S<a<(t/L)×(F/S) (2)

in the image display apparatus of the present invention.

In the present invention, a material of the buffer 20 is not especially limited only if Expression (1) and preferably Expression (2) are satisfied, but in concrete terms, such a metal as Ag and Al, and such a metallic oxide as ZnO are used. If this buffer 20 is disposed on the rear plate 2 side, and the spacer 4 contacts two or more wirings, then each wiring can be insulated by using an insulating member for the buffer 20.

In the above embodiment, the buffer 20 is disposed on the side where the spacer 4 contacts the rear plate 2, but if the protrusion 21 of the spacer 4 exists in the face plate 1 side, the buffer 20 can be disposed on the side where the spacer 4 contacts the face plate 1. In the above embodiment, a plate type spacer 4 was shown, but a spacer of which shape is a column, prism or a cross-shape when viewed from the XY plane, can also be appropriately used in the present invention.

### EXAMPLES

The present invention will be described in more detail using examples. In each of the following examples, an electron source, in which n×m (n=480, m=100) number of surface-conduction electron-emitting devices, having an electron-emitting portion in a conductive film between device electrodes are matrix-wired using m number of X direction wirings and n number of Y direction wirings, is used as a multi-electron beam source.

### Example 1

In this example, the image display apparatus having the configuration in FIG. 2 is created. As a spacer 4, a glass plate spacer of which length (X direction) is 108 mm, width (Z direction) is 2 mm, thickness (Y direction) is 0.26 mm, height L of the protrusion 21 at the end face is a maximum of 3 μm, and material is the same quality as the rear plate 2, is prepared.

The thickness T1 of the face plate 1 is 2.8 mm, thickness T2 of the rear plate 2 is 2.8 mm, and distance D between the substrates is 2 mm. The inner dimension W1 of the supporting frame 3 in the X direction is 112 mm, and the inner dimension W2 thereof in the Y direction is 72 mm. The supporting frame 3 and the face plate 1 and rear plate 2 are hermetically bonded by frit glass (not illustrated). The spacers 4 are evenly disposed in the Y direction with pitch P1=20 mm, and the number of spacers is three. The image display apparatus is constituted by these composing members.

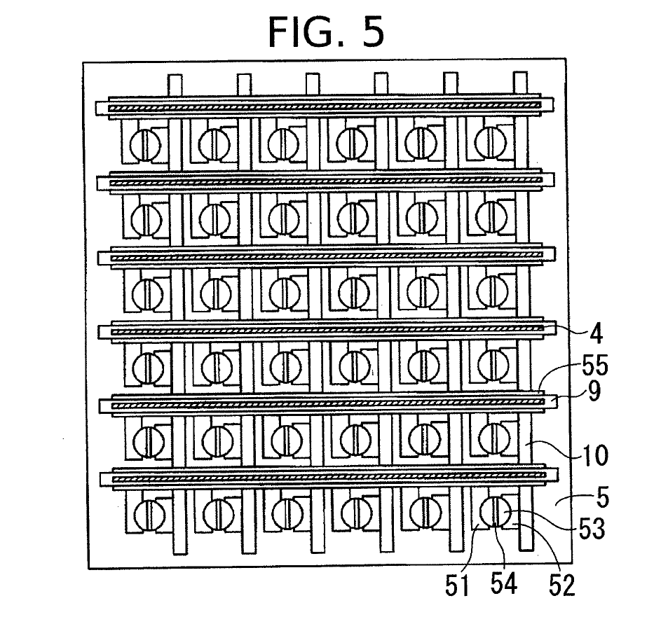

Fabrication of the display panel of this example will be described in detail with reference to FIG. 5. First the electron source substrate 5, in which the buffer 20, X direction wirings 9, Y direction wirings 10, inter-layer insulating layer 55, device electrodes 51 and 52 of the surface-conduction electron-emitting device, and a conductive film 54 are formed in advance, is secured to the rear plate 2. For the buffer 20, four types (Ag (1), ZnO, Al, Cu) in Table 1 are prepared. The thickness of each type is 20 μm.

The spacers 4 are secured on the X direction wirings 9 (line width=300 μm) on the substrate 5 via the buffer 20 with equal interval, to be in parallel with the X direction wirings 9. Then the face plate 1, where the fluorescent film 6 and metal back 7 are attached on the inner face, is disposed 2 mm above the substrate 5 via the supporting frame 3, and the respective bonding portions of the rear plate 2, face plate 1 and supporting frame 3 are secured. The bonding portion of the substrate 5 and rear plate 2, bonding portion of the rear plate 2 and supporting frame 3, and the bonding portion of the face plate 1 and supporting frame 3, are sealed by coating frit glass (not illustrated), and baking in atmospheric air at 400° C. to 500° C. for 10 minutes or longer.

In this example,

F=P×A

=0.1[MPa]×(W1×W2)

=0.1 [MPa]×112×10⁻³ [m]×72×10⁻³ [m]

=8.064×10⁻⁴ [MPa·m²]

The area of the contact portion is approximately 1/100 of the sectional area of the spacer 4. This is because the contact portion of the spacer 4 and the X direction wiring 9 is decreased by the distribution that is generated in the heights of the X direction wirings 9 by existing of wirings of the underlayer, other than the X direction wirings 9.

The area of the contact portion was measured by disassembling the display apparatus, and measuring the impression of the spacer 4 generated in the buffer 20 using a laser microscope (VK-8500, made by Keyence Corp.). In concrete terms, the height profile of the 1 to 4 mm² contact portion is obtained from 10 to 100 locations using a laser microscope, and the area of the portion where the shape has been changed by contacting the spacer 4 is calculated. This calculation is performed for all spacers 4, and the total area of the contact portions is calculated. In concrete terms,

S=0.26×10⁻³ [m]×108×10⁻³ [m]×3×0.01

=8.42×10⁻⁷ [m²]

F/S=8.064×10⁻⁴[MPa·m²]/8.42×10⁻⁷ [m²]

=958 MPa

Since t=20 μm and L=3 μM,

(t/(0.6×L))×F/S

=((20×10⁻⁶)/(0.6×3×10⁻⁶))×958 [MPa]

=11.11×958 [MPa]

=10643 [MPa]

is established. In other words, Expression (1) becomes

958 MPa<a<10643 MPa

Also,

(t/L)×(F/S)

=((20×10⁻⁶)/(3×10⁻⁶))×958 [MPa]

=6.67×958[MPa]

=6390 [MPa]

is established. In other words, Expression (2) becomes

958 MPa<a<6390 MPa

TABLE 1

| Buffer | Ag (1) | ZnO | Cu | Al |
|---|---|---|---|---|
| Elastic modulus [MPa] | 4346 | 1140 | 13780 | 7550 |
| Δt [μm] | 4.41 | 16.80 | 1.39 | 2.54 |

The elastic modulus a of Al is 7550 MPa, which satisfies the above Expression (1). At this time, the thickness Δt of the portion embedded in the buffer 20 of Al, out of the height L=3 μm of the protrusion 21, is

Δt=(t/a)×(F/S)

=((20×10⁻⁶ [m])/7550 [MPa])×958 [MPa]

=2.54×10⁻⁶ [m]

Therefore, 60% or more of the protrusion 21 is embedded in the buffer 20, and the inclination of the spacer 4 can be controlled to be ±0.3° or less.

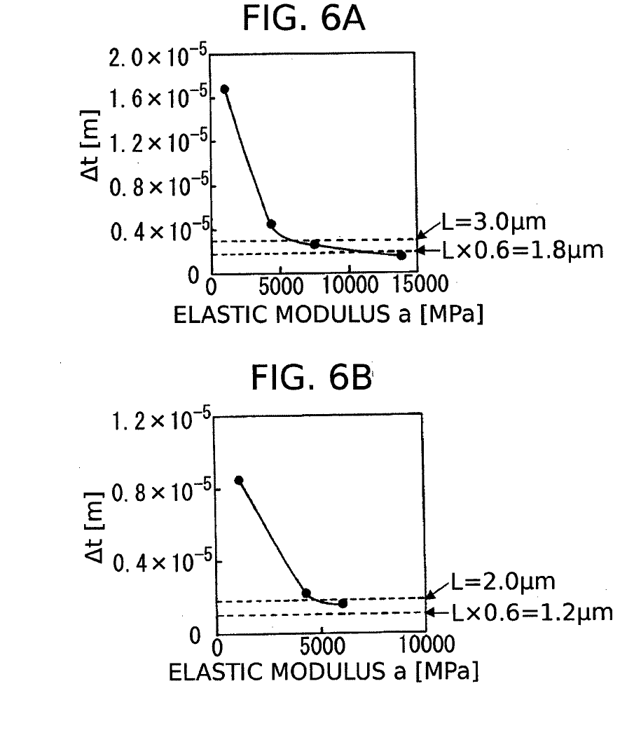

Table 1 shows the numeric values of Δt in other materials. FIG. 6A shows the relationship of the elastic modulus a and Δt in Example 1. In the case of ZnO and Ag (1) as well, just like Al, Expression (1) is satisfied, and the spacer 4 can be installed approximately perpendicular to the substrate 5, by controlling the inclination of the spacer 4 with respect to the substrate 5 due to the protrusion 21 on the surface of the spacer 4. In this case, the inclination of these spacers 4 is also ±0.3° or less. In the case of Cu however, Expression (1) is not satisfied, so Δt becomes

Δt=(t/a)×(F/S)

=((20×10⁻⁶)/13780[MPa])×958 [MPa]

=1.39×10⁻⁶ [m]

and 60% or more of the protrusion 21 is not embedded in the buffer 20, therefore the inclination of the spacer 4 with respect to the plates 1 and 2, due to this protrusion 21, cannot be controlled, and the inclination of the spacer 4 exceeds ±0.3°. As a result image quality deteriorates, and in some cases the spacer 4 falls down during or after fabrication of the display panel.

In the case of Ag (1) and ZnO, Expression (2) is also satisfied, therefore Δt exceeds the height L=3 μm of the protrusion 21 in both cases, and the protrusion 21 is completely embedded in the buffer 20, and the inclination of the spacer 4 can be controlled to be ±0.1° or less.

### Example 2

Example 2 of the present invention is described, focusing only on the aspects that are different from Example 1. In this example, three types (Ag (1), Ag (2) and ZnO) in Table 2 are prepared as the buffer 20. The thicknesses of each type is 10 μm. As the spacer 4, a glass plate spacer, of which length (X direction) is 108 mm, width (Z direction) is 2 mm, thickness (Y direction) is 0.26 mm, height L of the protrusion 21 of the end face is 2 μm at the maximum, and material is the same quality as the rear plate 2, is prepared. Ag (1) and Ag (2) have different elastic moduluses, since the fabrication methods for the buffer 20 are different.

In this example, just like Example 1,

F=8.064×10⁻⁴[MPa·m²]

S=8.42×10⁻⁷ [m²]

F/S=958 [MPa]

Since t=10 μm and L=2 μm,

(t/(0.6×L))×(F/S)

=((10×10⁻⁶ [m])/(0.6×2×10⁻⁶ [m]))×958 [MPa]

=8.33×958 [MPa]

=7980 [MPa]

is established. In other words, Expression (1) becomes

958 MPa<a<7980 MPa

Also

(t/L)×(F/S)

=((10×10⁻⁶ [m])/(2×10⁻⁶ [m]))×958 [MPa]

=5×958 [MPa]

=4790 [MPa]

is established. In other words, Expression (2) becomes

958 MPa<a<4790 MPa

TABLE 2

| Buffer | Ag (1) | Ag (2) | ZnO |
|---|---|---|---|
| Elastic modulus [MPa] | 4346 | 6111 | 1140 |
| Δt [μm] | 2.20 | 1.57 | 8.40 |

The elastic modulus a of Ag (1) is 4346 MPa, which satisfies the above Expressions (1) and (2). At this time, the thickness Δt of the portion embedded in the buffer Ag (1), out of the height L=2 μm of the protrusion 21, is

Δt=(t/a)×(F/S)

=((10×10⁻⁶ [m])/4346 [MPa])×958 [MPa]

=2.2×10⁻⁶ [m]

Therefore the protrusion 21 is completely embedded in the buffer 20, and the inclination of the spacer 4, with respect to the substrate 5, due to the protrusion 21 on the surface of the spacer 4, is controlled, and the spacer 4 can be installed approximately perpendicular to the substrate 5. The inclination of the spacer 4 at this time is ±0.1° or less.

Table 2 shows the numeric values of Δt in other materials. FIG. 63 shows the relationship of the elastic modulus a and Δt in Example 2. In the case of ZnO, just like Ag (1), Expressions (1) and (2) are satisfied, and the spacer 4 can be installed approximately perpendicular to the substrate 5, by controlling the inclination of the spacer 4 with respect to the substrate 5 due to the protrusion 21 on the surface of the spacer 4. In this case, the inclination of the spacer is ±0.1° or less, and good image quality can be obtained in the image display apparatus using this spacer 4.

Ag (2) satisfies Expression (1), but not Expression (2). In other words,

Δt=(t/a)×(F/S)

=((10×10⁻⁶ [m])/6111[MPa])×958 [MPa]

=1.57×10⁻⁶ [m]

Since 60% or more, but not all, of the protrusion 21 is embedded in the buffer 20, the inclination of the spacer 4, with respect to the substrate 5 due to the protrusion 21 on the surface of the spacer 4, is in a ±3° or less range.

### Example 3

Example 3 of the present invention is described, focusing only on the aspects that are different from Example 1. In this example, the spacers 4 are secured to be perpendicular to the X direction wirings 9 (line width=300 μm) on the substrate 5, that is, directly on top of the Y direction wirings 10 via the buffers 20 with equal interval, to be in parallel with the Y direction wirings 10. As the buffer 20, an insulating ZnO, of which elastic modulus a is 1140 MPa and thickness t is 10 μm, is used.

In this example, Expression (2), that is

F/S=957 MPa<a<(t/L)×F/S=4790 MPa

is satisfied just like Example 1. Therefore the inclination of the spacer 4, with respect to the substrate 5 due to the protrusion 21 on the surface of the spacer 4, can be controlled, and the spacer 4 can be installed approximately perpendicular to the substrate 5. Although the spacer 4 is disposed extending over a plurality of wirings, insulation between the wirings can be maintained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-172974, filed on Jul. 24, 2009, which is hereby incorporated by reference herein in its entirety.

What is claimed is:

1. An image display apparatus, comprising:
a rear plate having electron-emitting devices;
a face plate having a light emitting member which emits light by irradiation of electrons emitted from the electron-emitting devices;
a spacer disposed between the rear plate and face plate, and having a protrusion on the side facing the rear plate or face plate; and
a buffer disposed between the rear plate or face plate and the protrusion, wherein
the following Expression (1) is satisfied:
F/S≦a≦(t/(0.6×L))×(F/S) (1)
where L [m] denotes a height of the protrusion, t [m] denotes a thickness of the buffer in a position in contact with the outer periphery of the spacer, a [MPa] denotes an elastic modulus of the buffer, F [MPa·m²] denotes the total amount of force applied to a contact portion between the buffer and the spacer, and S [m²] denotes the total area of the contact portion.

2. The image display apparatus according to claim 1, wherein the following Expression (2) is satisfied:
F/S≦a≦(t/L)×(F/S) (2)
where L [m] denotes a height of the protrusion, t [m] denotes a thickness of the buffer in a position in contact with the outer periphery of the spacer, a [MPa] denotes an elastic modulus of the buffer, F [MPa·m²] denotes the total amount of force applied to a contact portion between the buffer and the spacer, and S [m²] denotes the total area of the contact portion.

3. The image display apparatus according to claim 1, wherein the buffer is an insulating member.
